(19) United States
(12) Patent Application Publication
(10) Pub. No.: US 2026/0041004 A1
(43) Pub. Date: Feb. 5, 2026

(54) THREE-DIMENSIONAL INTEGRATED CIRCUITS, ELECTRONIC SYSTEMS, AND METHODS OF FABRICATING A THREE-DIMENSIONAL INTEGRATED CIRCUIT

(71) Applicant: Micron Technology, Inc., Boise, ID (US)

(72) Inventors: Jason Kung, Taichung City (TW); Lihao Lyu, Hsinchu City (TW); Jong Sik Paek, Taichung (TW); Ko Han Lin, Taichung (TW); Yichen Wang, Taichung (TW)

(21) Appl. No.: 19/255,139

(22) Filed: Jun. 30, 2025

Related U.S. Application Data
(60) Provisional application No. 63/677,282, filed on Jul. 30, 2024.

(51) Int. Cl. H01L 23/00; H01L 25/18

(52) U.S. Cl. CPC H01L 24/05; H01L 24/03; H01L 24/08; H01L 25/18; H01L 2224/0361; H01L 2224/0384; H01L 2224/05647; H01L 2224/08147; H01L 2924/1438

(57) ABSTRACT

A three-dimensional integrated circuit includes a first microelectronic device structure including first conductive pads, a first dielectric material, and first multi-material conductive pads. The first multi-material conductive pads include a first conductive material and a second conductive material. The three-dimensional integrated circuit further includes a second microelectronic device structure including second conductive pads and a second dielectric material. The first conductive pads and the first multi-material conductive pads of the first microelectronic device structure are bonded to the second conductive pads of the second microelectronic device structure, and the first dielectric material of the first microelectronic device structure is bonded to the second dielectric material of the second microelectronic device structure. Related electronic system and methods of fabricating a three-dimensional integrated circuit are also disclosed.

### CROSS-REFERENCE TO RELATED APPLICATION

This application claims the benefit under 35 U.S.C. § 119 (e) of U.S. Provisional Patent Application Ser. No. 63/677,282, filed Jul. 30, 2024, the disclosure of which is hereby incorporated herein in its entirety by this reference.

### TECHNICAL FIELD

This disclosure relates generally to the field of microelectronic device design and fabrication. More specifically, the disclosure relates to methods of forming three-dimensional integrated circuits, and to related microelectronic devices and electronic systems.

### BACKGROUND

In the field of semiconductor technology, the demand for higher performance, lower power consumption, and smaller form factors has been a constant driving force. Traditional two-dimensional (2D) planar technologies have been pushed to their limits to meet these demands. As a result, the industry has turned to other solutions, one of which is three-dimensional integrated circuit (3DIC) technology.

3DIC technology involves the vertical stacking of different chips or wafers into a single package. This is achieved through the use of through-silicon vias (TSVs) or hybrid bonding, which provide interconnections within the package. The 3DIC architecture increases functional density at the same or reduced power, while maintaining the same or smaller area. This results in a smaller package for electronic devices, offering significant advantages in terms of efficiency, power, performance, and form factor.

The process of stacking in 3DIC technology involves vertically stacking two or more integrated circuits, also known as chips or dies, and joining them together into a single integrated circuit (IC) package. The chips or dice are typically connected within the package using solder balls or small diameter wires. In some instances, such bonding may be completed by sintering, which exposes the dice to elevated temperatures and pressures. In some situations, such exposure may lead to damage to the dielectric material at the interface between the dice.

### BRIEF DESCRIPTION OF THE DRAWINGS

FIGS. 1A-1J are simplified, partial cross-sectional views illustrating a method of forming a three-dimensional integrated circuit, in accordance with embodiments of the disclosure.

FIGS. 2A and 2B are simplified, partial cross-sectional views illustrating a method of forming a three-dimensional integrated circuit, in accordance with embodiments of the disclosure.

FIG. 3 is a flow chart showing a method for joining microelectronic device structures to form a three-dimensional integrated circuit, in accordance with embodiments of the disclosure.

FIGS. 4A and 4B are a flow chart showing a method for forming a three-dimensional integrated circuit, in accordance with embodiments of the disclosure.

FIG. 5 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a three-dimensional integrated circuit for an electronic device, such as a memory device). The electronic device may, for example, be a 3D NAND Flash memory device. The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random-access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization, or other known methods.

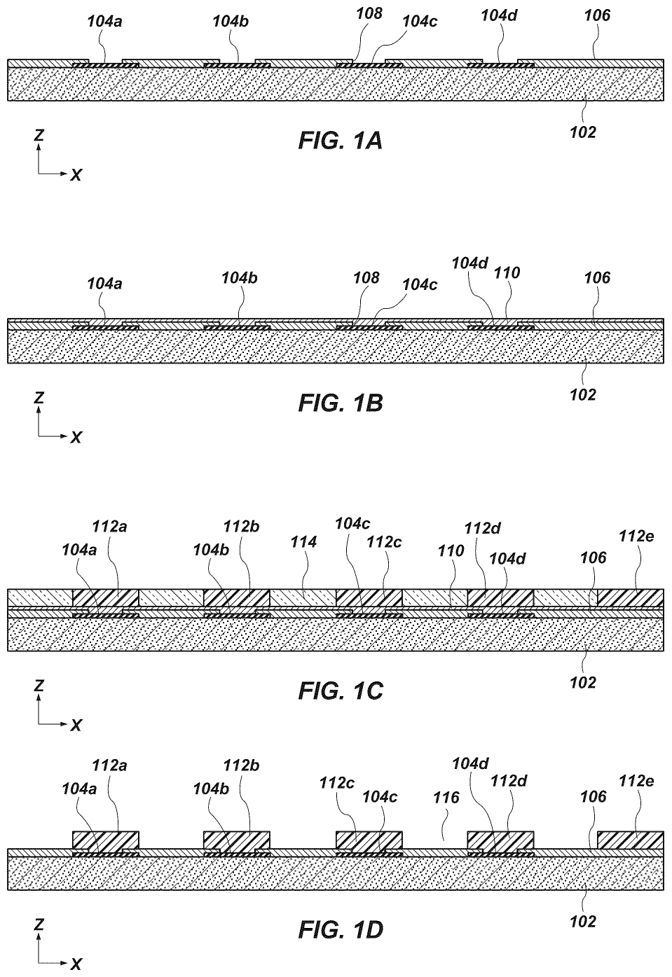

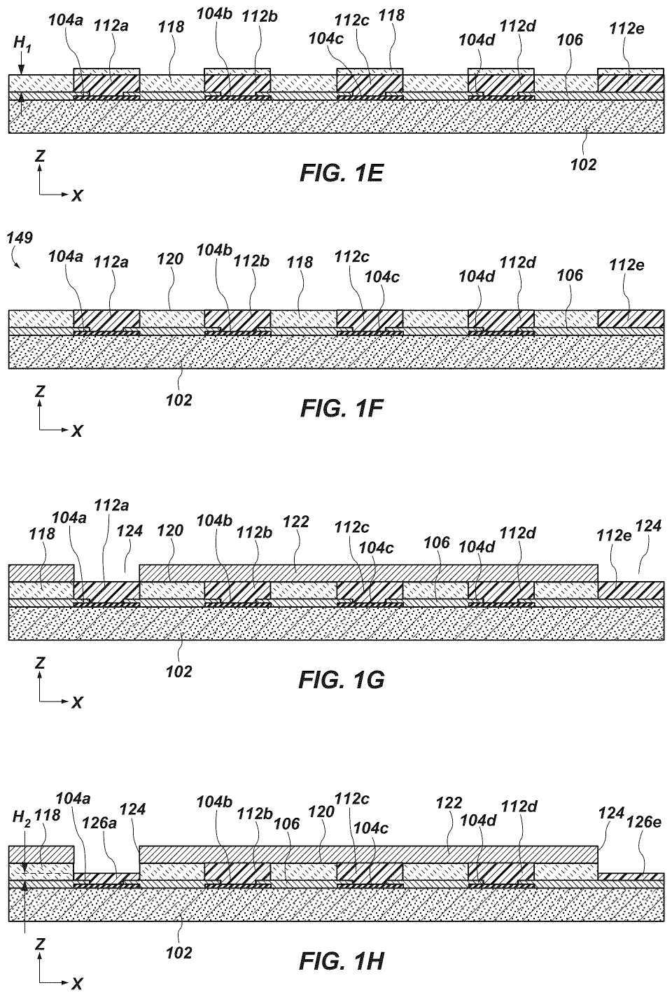

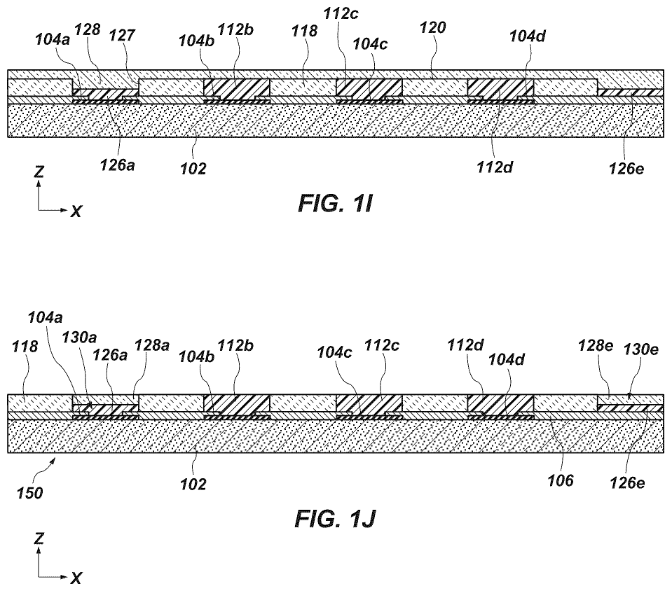

FIGS. 1A-1J are simplified, partial cross-sectional views illustrating a method of forming a three-dimensional integrated circuit. FIG. 1A shows a wafer or chip 102, such as a wafer or chip 102 that is to be integrated into a three-dimensional integrated circuit for a memory storage device. As shown in FIG. 1A, bond pads 104a-104d (collectively referred to as bond pads 104) may be formed on an upper surface of the chip 102. The bond pads 104 may include active bond pads (e.g., bond pads that are configured to transmit information to and from the underlying (e.g., in the Z-direction) chip 102) and inactive or so-called “dummy” bond pads (e.g., bond pads that are not communicatively coupled to the underlying chip 102). In some embodiments, the bond pad 104a is a dummy bond pad and the bond pads 104b-104d are active bond pads. However, other configurations are also possible, such as all of the bond pads 104a-104d being active bond pads. The bond pads 104 may be formed from a conductive material such as those described above. In some embodiments, the bond pads 104 are formed from aluminum or an aluminum alloy. The bond pads 104 may be formed on the chip 102 in any suitable manner such as those described above.

A first insulative material 106 may be formed on the upper surface of the chip 102. The first insulative material 106 may be formed via any suitable process and may be formed between the bond pads 104 (e.g., in the X-direction) on the upper surface of the chip 102. The first insulative material 106 may be formed to create openings 108 above (e.g., in the Z-direction) the bond pads 104. By way of example only, conventional photolithography techniques may be used to form and pattern the first insulative material 106, forming the openings 108 that expose a portion of an upper surface of the bond pads 104.

In FIG. 1B, a seed material 110 may be formed over the bond pads 104 and the first insulative material 106. The seed material 110 may be fabricated by any suitable method such as those discussed above. The seed material 110 may be formed from a conductive material such as a metal material. For example, the seed material 110 may be formed via physical vapor deposition. The seed material 110 may fill in the openings 108 in the first insulative material 106 and substantially cover the upper surface of the first insulative material 106.

In FIG. 1C, the method includes forming conductive pads 112a-112e (collectively referred to as conductive pads 112) and a first sacrificial material 114 on the seed material 110. The conductive pads 112 may be vertically adjacent to the bond pads 104 or vertically adjacent to the first insulative material 106. The conductive pads 112 and first sacrificial material 114 may be formed by any suitable process such as those described above. By way of example only, the first sacrificial material 114 may be formed over the seed material 110 and patterned by photolithography techniques to expose the seed material 110 overlying the bond pads 104. An electroplating process may subsequently be conducted to selectively form the conductive pads 112 over the portions of the seed material 110 exposed through the patterned first sacrificial material 114. The conductive pads 112 may be formed from a conductive material such as those described above. In some embodiments, the conductive pads 112 may be formed from copper or a copper alloy. Dimensions of the conductive pads 112 may be substantially similar to the dimensions of the bond pads 104. However, the conductive pads 112 may be relatively smaller or relatively larger than the bond pads 104.

In FIG. 1D, a removal process (e.g., an etching process or other suitable process) may be utilized to remove the first sacrificial material 114 and underlying portions of the seed material 110. Accordingly, voids 116 may be formed between laterally adjacent conductive pads 112 (e.g., laterally adjacent in the x direction) and above the first insulative material 106.

In FIG. 1E, a second insulative material 118 is formed onto the chip 102. For example, the second insulative material is deposited over the first insulative material 106 and the conductive pads 112, substantially filling the voids 116 between the laterally adjacent conductive pads 112. The second insulative material 118 may be a material that fills the voids 116 and forms over the conductive pads 112. The second insulative material 118 may be deposited via any suitable process such as chemical vapor deposition. The second insulative material 118 may be any suitable material such as those described above. The second insulative material 118 may be a dielectric material, such as a silicon oxide material, a silicon nitride material, or a polymer. In some embodiments, the second insulative material 118 is silicon dioxide. In other embodiments, the second insulative material 118 is silicon nitride. In yet other embodiments, the second insulative material 118 is a polyimide. The second insulative material 118 may be formed in the voids 116 to an initial height H₁.

As shown in FIG. 1F, a portion of the second insulative material 118 overlying the conductive pads 112 may be removed, exposing the conductive pads 112. The second insulative material 118 may be removed, for example, by chemical mechanical planarization or polishing. The chemical mechanical planarization or polishing may also provide a desired surface finish on an upper surface 120 of the second insulative material 118 for later processing. An improved surface finish may decrease surface roughness of the conductive pads 112. The upper surface 120 of the second insulative material 118 may be substantially coplanar with an upper surface of the conductive pads 112. The microelectronic device structure 149 shown in FIG. 1F may be a microelectronic device structure suitable for bonding with additional microelectronic device structures to form a three-dimensional integrated circuit as will be described in more detail below. In other words, in some embodiments, the microelectronic device structure 149 may forego the processing steps described below with reference to FIGS. 1G-1J.

In FIG. 1G, a second sacrificial material 122 is formed on the upper surface 120 of the second insulative material 118 and on the conductive pads 112 and patterned to form openings 124. The second sacrificial material 122 may be deposited via any suitable process such as those discussed above. For example, the second sacrificial material 122 may be a photoresist material, which is patterned to form the openings 124, which expose one or more of the conductive pads 112. As shown in FIG. 1G, the openings 124 may expose conductive pads 112a, 112e, with conductive pads 112b-112d protected by the overlying second sacrificial material 122.

In some embodiments, the one or more exposed conductive pads 112a, 112e are associated with bond pads 104. The location of the openings 124 corresponds to the location where multi-material conductive pads 130a, 130e (see FIG. 1J) are ultimately to be formed. In some embodiments, the one or more exposed conductive pads 112 are associated with bond pads 104 that include one or both of active bond pads or dummy bond pads.

In FIG. 1H, the one or more conductive pads 112 (e.g., conductive pads 112a, 112e) that are exposed through the openings 124 in the second sacrificial material 122 are etched to form recessed conductive pads 126a, 126e having a height H₂. For example, after etching, the height H₂ of the recessed conductive pads 126a, 126e in the Z-direction is less than the height H₁ of the conductive pads 112 (e.g., conductive pads 112b-112d) that were not exposed (see FIG. 1E). In other words, the conductive pads 112b-112d underlying the second sacrificial material 122 may be protected from etching. In some embodiments, the height H₂ of the recessed conductive pads 126a, 126e may be between about 50% and about 100% of the height H₁ of the conductive pads 112. In some embodiments, the height H₂ of the recessed conductive pads 126a, 126e may be between about 60% and about 90% of the height H₁ of the conductive pads 112.

In FIG. 1I, the second sacrificial material 122 may be substantially completely removed from the upper surface 120 of the second insulative material 118, exposing the recessed conductive pads 126a, 126e, the conductive pads 112b-112d, and the second insulative material 118. Holes 127 are formed above the recessed conductive pads 126a, 126c. A conductive material 128 may be formed on the second insulative material 118, the conductive bond pads 112b-112d, and the recessed conductive pads 126a, 126e. The conductive material may be an inorganic material selected to exhibit improved diffusion properties and migration properties, decreasing a thermal budget for bonding components of a three-dimensional integrated circuit 160, as will be described in more detail below. The conductive material 128 may substantially fill the holes 127 above the recessed conductive pads 126a, 126e and may be formed over the second insulative material 118 and the conductive pads 112b-112d. The conductive material 128 may be deposited via any suitable process such as those described above. In some embodiments, the conductive material 128 is formed using chemical vapor deposition. In some embodiments, the conductive material 128 is formed from gold, platinum, tantalum, nickel, or other materials, or an alloy thereof.

As shown in FIG. 1J, the conductive material 128 undergoes chemical mechanical planarizing or polishing to remove the conductive material 128 from the upper surface 120 of the second insulative material 118 and from the conductive pads 112b-112d, leaving a portion of the conductive material 128 over the recessed conductive pads 126a, 126c (e.g., conductive material 128a, 128c). An upper surface of the conductive material 128a, 128c may be substantially coplanar with an upper surface of the second insulative material 118 and the conductive pads 112b-112d. The conductive material 128a, 128e and the recessed conductive pads 126a, 126e together form multi-material conductive pads 130a, 130e (referred to collectively as multi-material conductive pads 130). A thickness of the conductive material 128a, 128e depends on the height of the recessed conductive pads 126a, 126e and the depth of the holes 127. The combined height (dimension in the Z-direction) of the multi-material conductive pads 130a, 130e (e.g., the combined height of the recessed conductive pads 126a, 126e and the conductive material 128a, 128c) may be substantially equal to that of the conductive pads 112b-112d protected by the second sacrificial material 122. As shown in FIG. 1J, the multi-material conductive pads 130 may be vertically adjacent to bond pad 104 or may directly overlie the first insulative material 106. In some embodiments, the conductive material 128a, 128e may account for between about 0% and about 50% of a total thickness of the multi-material conductive pads 130. In some embodiments, the thickness of the conductive material 128a, 128c may be between about 10% and about 40% of the total thickness of the multi-material conductive pads 130. The resulting microelectronic device structure 150 shown in FIG. 1J is configured to be attached to other microelectronic device structures to form a three-dimensional integrated circuit.

The multi-material conductive pads 130 may function to increase diffusion bonding between multiple microelectronic device structures 150 of the three-dimensional integrated circuit. The recessed conductive pads 126a, 126e and the conductive material 128a, 128e of the multi-material conductive pad 130 may be a rigid structural material and provide increased mechanical strength to the microelectronic device structures 150. The multi-material conductive pads 130 may be configured as so-called “beams” to provide structural support to the three-dimensional integrated circuit, while the conductive pads 112b-112d may be configured as interconnects of the three-dimensional integrated circuit. In some embodiments, the multi-material conductive pads 130 may also be configured as interconnects of the three-dimensional integrated circuit as well as beams to provide structural support.

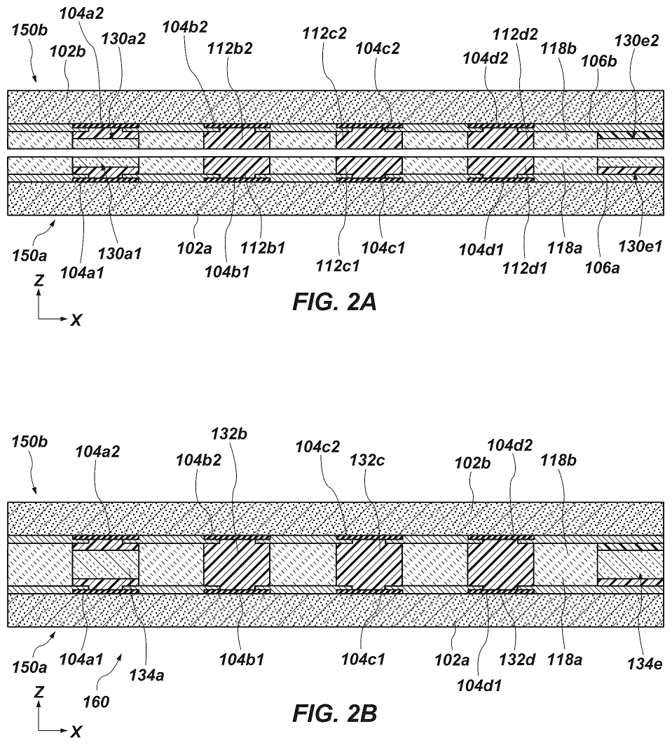

FIGS. 2A and 2B are simplified, partial cross-sectional views illustrating a method of forming a three-dimensional integrated circuit, in accordance with embodiments of the disclosure. In FIG. 2A, a first microelectronic device structure 150a may include a first wafer or chip 102a with first bond pads 104a1-104dl formed on the first wafer 102a as described above. The first microelectronic device structure 150a may be substantially similar to the microelectronic device structure 150 in FIG. 1J. One or more first multi-material conductive pads 130al and first conductive pads 112b1, 112c1, -112d1 may be disposed on and associated with the first bond pads 104a1-104d1. One or more first multi-material conductive pads 130e1 may also be disposed on the first insulative material 106a. In some embodiments, one or more of the first bond pads, such as first bond pad 104al associated with the first multi-material conductive pads, such as first multi-material conductive pad 130al, may be dummy pads. A first dielectric material 118a may be horizontally adjacent to (e.g., in the X-direction) the first multi-material conductive pads 130a1, 130e1 and the first conductive pads 112b1-112d1.

A second microelectronic device structure 150b may be configured to be bonded to the first microelectronic device structure 150a. The second microelectronic device structure 150b may be substantially similar to the first microelectronic device structure 150a in that the second chip may include a second wafer or chip 102b with second bond pads 104a2-104d2 formed on the second wafer 102b as described above. One or more second multi-material conductive pads 130a2 and second conductive pads 112b2-112d2 may be disposed on and associated with the second bond pads 104a2-104d2. One or more second multi-material conductive pads 130e2 may also be disposed on the first insulative material 106b. In some embodiments, one or more of the second bond bads, such as second bond pad 104a2 associated with the second multi-material conductive pads, such as second multi-material conductive pad 130a2, may be dummy pads. A second dielectric material 118b may be horizontally adjacent to (e.g., in the X-direction) the second multi-material conductive pads 130a2, 130e2 and the second conductive pads 11262-112d2.

The first microelectronic device structure 150a and the second microelectronic device structure 150b are aligned in the Z-direction such that the first conductive pads 112b1-112d1 are aligned with the second conductive pads 112b2-112d2, the first multi-material conductive pads 130a1, 130e1 are aligned with the second multi-material conductive pads 130a2, 130e2, and the first dielectric material 118a is aligned with the second dielectric material 118b.

As shown in FIG. 2B, the first microelectronic device structure 150a is brought into contact with the second microelectronic device structure 150b. Heat and pressure are applied to the first and second microelectronic device structure 150a, 150b in a metal diffusion bonding process to form a three-dimensional integrated circuit 160 having interconnects 132b, 132c, 132d and bonded multi-material conductive pads or “beams” 134a, 134c. The interconnects 132b-132d are formed by bonding of the first conductive pads 112b1-112d1 and the second conductive pads 112b2-112d2, and the bonded multi-material conductive pads 134a, 134e are formed by bonding of the first multi-material conductive pads 130a1, 130e1 to the second multi-material conductive pads 130a2, 130e2.

In the metal diffusion bonding process, the temperature and pressure cause atoms of the materials along a bonding interface to intersperse and bond. After bonding, the bonded multi-material conductive pads 134a, 134e exhibit different properties than the conductive material 128a, 128e alone before bonding. Without being bound by any theory, with the application of temperature and pressure, the atoms of the first multi-material conductive pads 130a1, 130e1 and the second multi-material conductive pads 130a2, 130e2 are believed to fill in voids along the bonding interface between the first and second microelectronic device structures 150a, 150b being bonded. Accordingly, when the microelectronic device structures 150a, 150b are maintained under the metal diffusion process conditions, the first and second multi-material conductive pads 130a1, 130e1, and 130a2, 130e2 are bonded together. Furthermore, the atoms of the first multi-material conductive pads 130a1, 130e1 and the second multi-material conductive pads 130a2, 130c2 migrate within the first multi-material conductive pads 130a1, 130e1 and the second multi-material conductive pads 130a2, 130c2 forming an alloyed material within the bonded multi-material conductive pads 134a, 134c. In addition, during the metal diffusion process, the first conductive pads 112b1-112d1 and the second conductive pads 112b2-112d2 are bonded together, and the first and second dielectric materials 118a, 118b are bonded together.

The presence of the first and second multi-material conductive pads 130a1, 130e1, 130a2, 130e2 in the microelectronic device structures 150a, 150b enable alloys to be formed during the metal diffusion process, which results in a more robust process. The metal diffusion process is more robust because the bonding temperature, bonding pressure, and bonding time to form the three-dimensional integrated circuit 160 may be reduced compared to conventional techniques that lack the first and second multi-material conductive pads 130a1, 130e1, 130a2, 130e2. The process also results in no visible interfaces between the materials, such as between the conductive pads 112b1-112d1 and 112b2-112d2 and between the first and second multi-material conductive pads 130a1, 130e1 and 130a2, 130e2. The first and second microelectronic device structures 150a, 150b, therefore, are bonded together in the Z-direction forming the three-dimensional integrated circuit 160. While FIG. 2B shows the first and second microelectronic device structures 150a, 150b bonded together, more than two microelectronic device structures may be bonded. In addition, the methods according to embodiments of the disclosure may also be used for wafer-to-wafer, die-to-die, or die-to-wafer bonding.

With the first and second multi-material conductive pads 130a1, 130c1, and 130a2, 130c2, including the conductive material 128a, 128c (see, e.g., FIGS. 1I and 1J), the multi-material conductive pads 130a, 130e may create an intermetallic compound during the metal diffusion bonding process, as mentioned above. That is, the materials of the multi-material conductive pads 130a1, 130e1, and 130a2, 130c2, may undergo an alloying process as the atoms along the interface between the first and second multi-material conductive pads 130a1, 130e1, and 130a2, 130e2 and within the first and second multi-material conductive pads 130a1, 130e1, and 130a2, 130c2 intersperse and bond during the metal diffusion process. The resulting intermetallic compound of the bonded multi-material conductive pads 134a, 134e may be an alloy that provides a relatively higher mechanical strength as compared to a single crystal metal, such as may be formed in the interconnects 132b-132d. The intermetallic compound may exhibit different properties, such as mechanical properties, than the conductive material. The higher mechanical strength of the bonded multi-material conductive pads 134a, 134e may provide structural protection to the three-dimensional integrated circuit 160 by protecting the bonded first and second dielectric materials 118a, 118b, which may be relatively fragile. The bonded multi-material conductive pads 134a, 134e, or “beams,” may provide structural support to the three-dimensional integrated circuit 160, while the interconnects 132b-132d communicatively/electrically connect the first and second microelectronic device structures 150a, 150b of the three-dimensional integrated circuit 160.

The three-dimensional integrated circuit 160 formed according to embodiments of the disclosure may exhibit an increased yield compared to conventional three-dimensional integrated circuit lacking the bonded multi-material conductive pads 134a, 134c. Because the bonded multi-material conductive pads 134a, 134e support the first and second dielectric material 118a, 118b, the risk of cracking the first and second dielectric material 118a, 118b during processing is reduced. Further, the decreased surface roughness on the upper surface 120 (see FIGS. 1F-1I) of the conductive pads 112b1-112d1 and 112b2-112d2 may enable improved diffusion bonding between the conductive pads 112b1-112d1 and 112b2-112d2, increasing the yield of the three-dimensional integrated circuits 160.

Furthermore, the bonded multi-material conductive pads 134a, 134c may decrease a thermal budget for a given pressure during the metal diffusion bonding process. In some embodiments, the thermal budget for metal diffusion bonding to form the bonded multi-material conductive pads 134a, 134c may be about 200° C. In some embodiments, the thermal budget for metal diffusion bonding to form the bonded multi-material conductive pads 134a, 134e may be as low as 150° C. The lower thermal budget used to bond the bonded multi-material conductive pads 134a, 134e may result in decreasing one or more of the bonding pressure, bonding temperature, or bonding time of the microelectronic device structures 150a, 150b during the metal diffusion bonding process to form the three-dimensional integrated circuit 160.

In some embodiments, the bonded multi-material conductive pads 134a, 134c, the first and second dielectric material 118a, 118b, and the interconnects 132b-132d may be formed sequentially based on a thermal budget for bonding each of the components. For example, the decreased thermal budget of the bonded multi-material conductive pads 134a, 134c may allow the bonding of the multi-material conductive pad 134a, 134e to be a first act in bonding the microelectronic device structures 150a, 150b. The dielectric material 118a, 118b may then be bonded in a second act based on a second thermal budget that is higher than the first thermal budget and differences in coefficient of thermal expansion. Finally, the interconnects 132b-132d may be formed in a third act based on a third thermal budget that is higher than the first thermal budget and the second thermal budget and differences in the coefficient of thermal expansion. In some embodiments, the dielectric material 118a, 118b may be bonded at room temperature in a process separate from a metal diffusion process.

It is noted that while the height of the multi-material conductive pads 130a1, 130e1, 130a2, 130e2, the height of first conductive pads 112b1-112d1 and second conductive pads 112b2-112d2, and the height of the first and second dielectric material 118a, 118b are shown to be substantially identical to create a substantially coplanar upper surface (e.g., upper surface 120 shown in FIGS. 1F-1I), this is not intended to be limiting. The heights of above-mentioned parts may be different. For example, the first conductive pads 112b1-112d1 and second conductive pads 112b2-112d2 may have a height (e.g., a dimension in the Z-direction) that is less than a height of the first and second insulative material and the multi-material conductive pads 130a1, 130c1, 130a2, 130c2. The height of each of the above-mentioned parts may be based on the coefficient of thermal expansion (“CTE”) of the materials used in the above-mentioned parts to accommodate expansion of the above-mentioned parts during a metal diffusion process.

For example, when the dielectric material 118a, 118b is a SiO₂ or SiN material, the insulative material may have a CTE that is less than that of a metal (such as Cu) in the first conductive pads 112b1-112d1 and second conductive pads 112b2-112d2. Therefore, the height of the dielectric material 118a, 118b may be greater than that of the first conductive pads 112b1-112d1 and second conductive pads 112b2-112d2. When the dielectric material 118a, 118b is a polymer, such as a polyimide, the CTE of the dielectric material 118a, 118b may be greater than that of the metal (such as Cu) in the first conductive pads 112b1-112d1 and second conductive pads 112b2-112d2. Therefore, the height of the dielectric material 118a, 118b may be less than that of the first conductive pads 112b1-112d1 and second conductive pads 112b2-112d2.

The bonded multi-material conductive pads 134a, 134e may exhibit an electrical performance that is reduced as compared to the bonded first and second conductive pads 112a, 112b. However, sufficient numbers of bonded first and second conductive pads 112a, 112b may be present to maintain or increase the overall electrical performance of the three-dimensional integrated circuit 160. Accordingly, as mentioned above, the first and second multi-material conductive pads 130a1, 130a2 may be formed over first bond pads 104al or second bond pads 104a2 that are inactive or dummy pads. The first and second multi-material conductive pads 130e1, 130e2 may also be formed over the first and second insulative material 106a 106b. The interconnects 132b-132d may be formed on first and second bond pads 104b1-104d1 and 104b2-104d2 that are active bond pads. The bond pads 104a1-104dl and 104a2-104d2 may thus include active bond pads (e.g., bond pads that are configured to transmit information to and from the underlying (e.g., in the Z-direction) chip 102a, 102b) and inactive or so-called “dummy” bond pads (e.g., bond pads that are not communicatively coupled to the underlying chip 102). In one embodiment, the bond pads 104a1, 104a2 are dummy bond pads and the bond pads 104b1-104d1 and 104b2-104d2 are active bond pads. However, this is merely one example and other configurations, such as all of the bond pads 104a1-104dl and 104a2-104d2 being active bond pads, may be used.

As mentioned above with respect to FIG. 1F, in addition to bonding the first microelectronic device structure 150a to the second microelectronic device structure 150b, each of which are similar to the microelectronic device structure shown in FIG. 1J, a three-dimensional integrated circuit having the features and advantages of the integrated circuit 160 may also be obtained by bonding a microelectronic device structure similar to microelectronic device structure 149 shown in FIG. 1F to a microelectronic device structure similar to the microelectronic device structure 150 shown in FIG. 1J. For similar reasons discussed above, the bonding of the multi-material conductive pads 130a, 130e of the microelectronic device structure 150 to the conductive pads 112a, 112e of the microelectronic device structure 149 may result in bonded multi-material conductive pads similar to the bonded multi-material conductive pads 134a, 134c shown in FIG. 2B. In other words, the presence of the multi-material conductive pads (e.g., conductive pads 130a, 130e of microelectronic device structure 150) in just one of the two microelectronic device structures to be bonded is sufficient to create an intermetallic compound in the resulting bonded multi-material conductive pads (e.g., beams), similar as described above. Therefore, a similar three-dimensional integrated circuit as integrated circuit 160 may be obtained by forming the multi-material conductive pads (e.g., multi-material conductive pads 130a, 130e) in one of the two microelectronic device structures to be bonded.

Therefore, according to some embodiments, a three-dimensional integrated circuit includes a first a first microelectronic device structure including first conductive pads, a first dielectric material, and first multi-material conductive pads. The first multi-material conductive pads include a first conductive material and a second conductive material. The three-dimensional integrated circuit further includes a second microelectronic device structure including second conductive pads and a second dielectric material. The first conductive pads and the first multi-material conductive pads of the first microelectronic device structure are bonded to the second conductive pads of the second microelectronic device structure, and the first dielectric material of the first microelectronic device structure is bonded to the second dielectric material of the second microelectronic device structure.

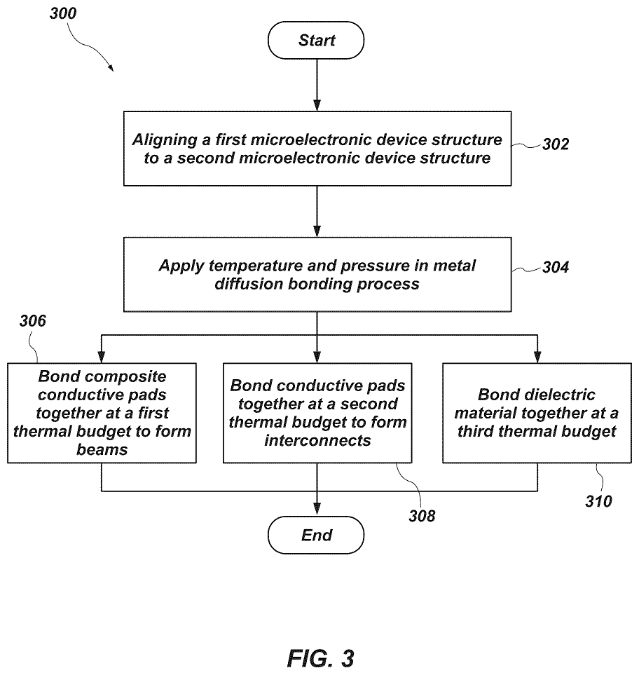

FIG. 3 is a flow chart showing a method 300 for joining microelectronic device structures to form a three-dimensional integrated circuit, such as integrated circuit 160 described with reference to FIG. 2B above. As shown in FIG. 3, the method 300 includes an act 302 of aligning a first microelectronic device structure to a second microelectronic device structure. For example, multi-material conductive pads 130a1, 130e1 of a first microelectronic device structure 150a may be aligned with multi-material conductive pads 130a2, 130c2 of a second microelectronic device structure 150b; conductive pads 112b1, 112c1, -112d1 of the first microelectronic device structure 150a may be aligned with conductive pads 112b2, 112c2, 112d2 of the second microelectronic device structure 150b; and first dielectric material 118a of the first microelectronic device structure 150a may be aligned with second dielectric material 118b of the second microelectronic device structure 150b (FIG. 2A).

In act 304 of the method 300, temperature and pressure are applied to the aligned microelectronic device structures in a metal diffusion bonding process. For example, temperature and pressure may be applied to the first microelectronic device structure 150a and the second microelectronic device structure 150b.

Acts 306, 308, and 310 of the method may be initiated simultaneously or may be timed to at least partially overlap one another. In act 306, the multi-material conductive pads are bonded together at a first thermal budget to form beams. For example, the multi-material conductive pads 130a1, 130e1 of the first microelectronic device structure 150a are bonded to the multi-material conductive pads 130a2, 130e2 of the second microelectronic device structure 150b to form beams 134a, 134c (bonded multi-material conductive pads) in the resulting three-dimensional integrated circuit (e.g., integrated circuit 160) (FIGS. 2A-2B).

In act 308, the conductive pads are bonded together at a second thermal budget to form interconnects. For example, the conductive pads 112b1, 112c1, -112d1 of the first microelectronic device structure 150a is bonded with the conductive pads 112b2, 112c2, 112d2 of the second microelectronic device structure 150b (FIGS. 2A-2B) to form interconnects 132b, 132c, 132d in the resulting three-dimensional integrated circuit (e.g., integrated circuit 160) (FIGS. 2A-2B).

In act 310, the dielectric material of each microelectronic device structure is bonded together at a third thermal budget. For example, the first dielectric material 118a of the first microelectronic device structure 150a is bonded with the second dielectric material 118b of the second microelectronic device structure 150b (FIGS. 2A-2B). With the multi-material conductive pads bonded, the conductive pads bonded and the dielectric material bonded, the first and second microelectronic devices are joined together to form a three-dimensional integrated circuit (e.g., integrated circuit 160 in FIG. 2B).

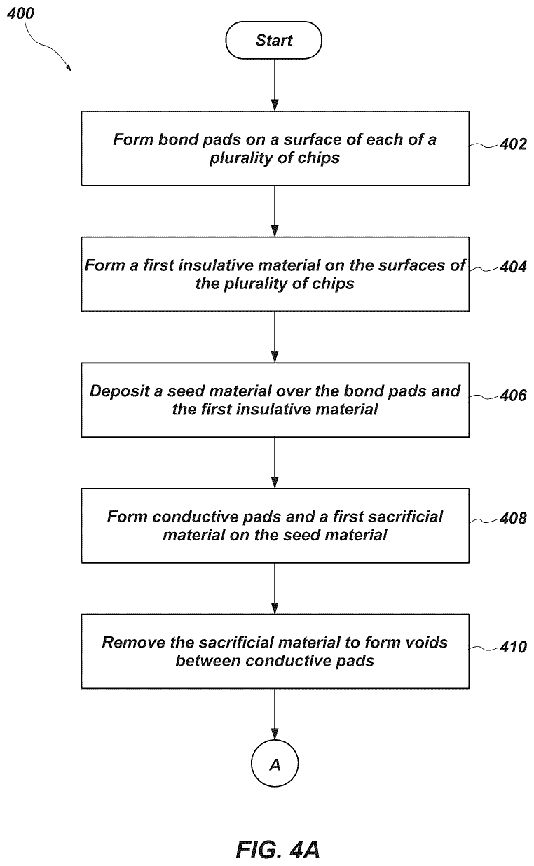

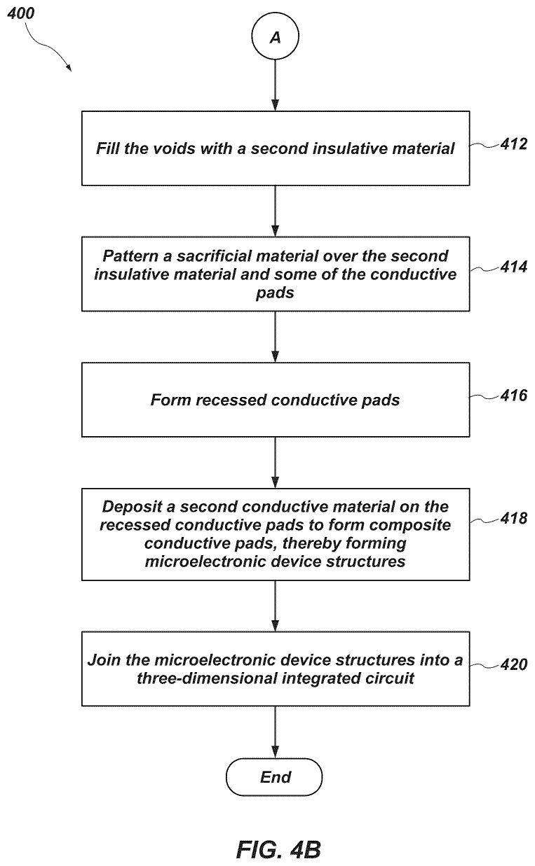

FIGS. 4A and 4B are a flow chart showing a method 400 for forming a three-dimensional integrated circuit, such as the integrated circuit 160 discussed above. In act 402, bond pads may be formed on a surface of chips. For example, as shown in FIG. 1A, bond pads 104a-104d are deposited on the surface of the chip 102.

In act 404, a first insulative material is formed on the surfaces of the chips. For example, as shown in FIG. 1A, a first insulative material 106 may be formed on the upper surface of the chip 102. In act 406, a seed material is deposited over the bond pads and the first insulative material. For example, as shown in FIG. 1B, a seed material 110 is deposited over the bond pads 104a-104d and the first insulative material 106.

In act 408, conductive pads and a first sacrificial material are formed on the seed material. For example, as shown in FIG. 1C, conductive pads 112a-112e and first sacrificial material 114 are formed over the bond pads 104a-104d and seed material 110. In act 410, the sacrificial material is removed to form voids between the conductive pads. For example, as shown in FIG. 1D, the first sacrificial material 114 (FIG. 1C) is removed, forming voids 116 between the conductive pads 112a-112c.

In act 412, the voids are filled with a second insulative material. For example, as shown in FIG. 1E, a second insulative material 118 is used to fill the voids 116 (FIG. 1D) between the conductive pads 112a-112e. In act 414, a sacrificial material is patterned over the second insulative material and some of the conductive pads. For example, as shown in FIG. 1G, second sacrificial material 122 is patterned over the conductive pads 112b-112d and over the second insulative material 118, exposing the conductive pads 112a, 112c.

In act 416, recessed conductive pads are formed. For example, as shown in FIG. 1H, conductive pads 112a, 112e that are exposed through the openings 124 in the second sacrificial material 122 are etched to form recessed conductive pads 126a, 126c. In act 418, a second conductive material is deposited on the recessed conductive pads to form multi-material conductive pads, thereby forming microelectronic device structures. For example, as shown in FIG. 1I, second sacrificial material 122 is removed and a conductive material 128 is deposited over the recessed conductive pads 126a, 126e, the conductive pads 112b-112d and the second insulative material 118. Excess conductive material 128 is then removed as shown in FIG. 1J to form the microelectronic device structure 150. In act 420, different microelectronic device structures may be joined into a three-dimensional integrated circuit, such as discussed above with reference to FIG. 3.

Therefore, according to some embodiments, a method for fabricating a three-dimensional integrated circuit is provided. The method includes forming first bond pads on a first die and forming second bond pads on a second die. First conductive pads are formed adjacent to the first bond pads of the first die, and second conductive pads are formed adjacent to the second bond pads of the second die. A portion of at least one, but not all, of the first conductive pads is removed to form at least one first recessed conductive pad, and a portion of at least one, but not all, of the second conductive pads is removed to form at least one second recessed conductive pad. A first conductive material is formed onto the at least one first recessed conductive pad to form at least one first multi-material conductive pad, and a second conductive material is formed onto the at least one second recessed conductive pad to form at least one second multi-material conductive pad. The first multi-material conductive pad and the second multi-material conductive pad are bonded to join the first die to the second die and to form the three-dimensional integrated circuit.

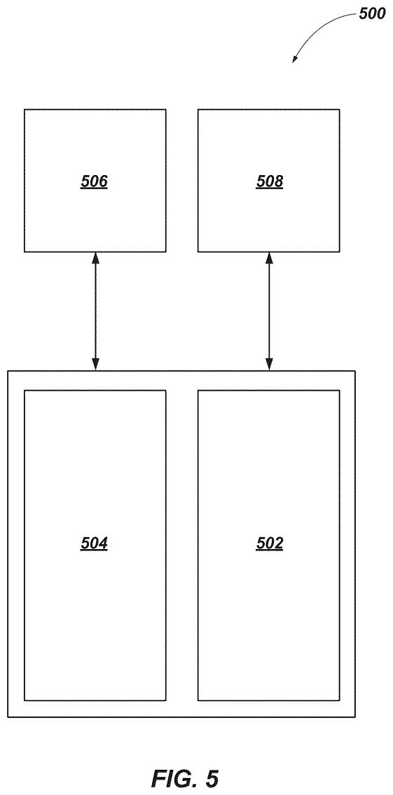

Microelectronic device structures (e.g., the microelectronic device structures 150a, 150b (FIGS. 2A-2B)) and three-dimensional integrated circuits (e.g., the integrated circuit 160 (FIG. 2B)) in accordance with embodiments of the disclosure may be used in embodiments of electronic systems of the disclosure. For example, FIG. 5 is a schematic block diagram of an illustrative electronic system 500 according to embodiments of disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 500 includes at least one memory device 502. The memory device 502 may include, for example, one or more of a microelectronic device structure (e.g., the microelectronic device structures 150a, 150b (FIGS. 2A-2B)) and a three-dimensional integrated circuit (e.g., the integrated circuit 160 (FIG. 2B)) previously described herein. The electronic system 500 may further include at least one electronic signal processor device 504 (often referred to as a “microprocessor”). The electronic signal processor device 504 may, optionally, comprise one or more of a microelectronic device structure (e.g., the microelectronic device structures 150a, 150b (FIGS. 2A-2B)) and a three-dimensional integrated circuit (e.g., the integrated circuit 160 (FIG. 2B)) previously described herein. While the memory device 502 and the electronic signal processor device 504 are depicted as two (2) separate devices in FIG. 5, in additional embodiments, a single (e.g., only one) memory/processor device having the functionalities of the memory device 502 and the electronic signal processor device 504 is included in the electronic system 500. In such embodiments, the memory/processor device may include one or more of a microelectronic device structure (e.g., the microelectronic device structures 150a, 150b (FIGS. 2A-2B)) and a three-dimensional integrated circuit (e.g., the integrated circuit 160 (FIG. 2B)) previously described herein.

The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, and/or a speaker. In some embodiments, the input device 506 and the output device 508 comprise a single touchscreen device that can be used both to input information to the electronic system 500 and to output visual information to a user. The input device 506 and the output device 508 may communicate electrically with one or more of the memory device 502 and the electronic signal processor device 504.

Accordingly, in some embodiments, an electronic system includes an input device, an output device, a processor device operably connected to the input device and the output device, and a memory device operably connected to the processor device. The memory device includes a three-dimensional integrated circuit that includes a first microelectronic device structure including first multi-material conductive pads including a first conductive material and a second conductive material, and a second microelectronic device structure bonded to the first microelectronic device structure. The second microelectronic device structure includes second multi-material conductive pads including a third conductive material and a fourth conductive material. The second multi-material conductive pads are bonded to the first multi-material conductive pads.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A three-dimensional integrated circuit comprising:
a first microelectronic device structure comprising first conductive pads, a first dielectric material, and first multi-material conductive pads, the first multi-material conductive pads comprising a first conductive material and a second conductive material; and
a second microelectronic device structure comprising second conductive pads and a second dielectric material,
the first conductive pads and the first multi-material conductive pads of the first microelectronic device structure being bonded to the second conductive pads of the second microelectronic device structure, and the first dielectric material of the first microelectronic device structure being bonded to the second dielectric material of the second microelectronic device structure.

2. The three-dimensional integrated circuit of claim 1, wherein the bonded first multi-material conductive pads and the second conductive pads comprise an intermetallic compound.

3. The three-dimensional integrated circuit of claim 2, wherein the intermetallic compound comprises a higher relative mechanical strength than that of the bonded first and second conductive pads.

4. The three-dimensional integrated circuit of claim 1, wherein the first conductive material comprises copper or a copper alloy, and wherein the second conductive material comprises gold or a gold alloy.

5. The three-dimensional integrated circuit of claim 1, wherein the first dielectric material and the second dielectric material comprise silicon oxide.

6. The three-dimensional integrated circuit of claim 1, wherein:
the first microelectronic device structure further comprises first bond pads including first active bond pads and first inactive bond pads, the first conductive pads disposed over the first active bond pads, and the first multi-material conductive pads disposed over the first inactive bond pads.

7. The three-dimensional integrated circuit of claim 1, wherein a thickness of the second conductive material of the first multi-material conductive pad is between about 10% and about 40% of a total thickness of the first multi-material conductive pad.

8. An electronic system comprising:
an input device;
an output device;
a processor device operably connected to the input device and the output device; and
a memory device operably connected to the processor device and comprising:
a three-dimensional integrated circuit comprising:
a first microelectronic device structure comprising first multi-material conductive pads including a first conductive material and a second conductive material, and
a second microelectronic device structure bonded to the first microelectronic device structure, the second microelectronic device structure comprising second multi-material conductive pads including a third conductive material and a fourth conductive material, the second multi-material conductive pads bonded to the first multi-material conductive pads.

9. The electronic system of claim 8, wherein:
the first microelectronic device structure further comprises first inactive bond pads, and the first multi-material conductive pads are disposed over the first inactive bond pads; and
the second microelectronic device structure further comprises second inactive bond pads, and the second multi-material conductive pads are disposed over the second inactive bond pads.

10. The electronic system of claim 8, wherein:
the first conductive material comprises copper or a copper alloy, and the second conductive material comprises gold or a gold alloy; and
the third conductive material comprises copper or a copper alloy, and the fourth conductive material comprises gold or a gold alloy.

11. The electronic system of claim 8, wherein:
a thickness of the second conductive material of the first multi-material conductive pad is between about 10% and about 40% of a total thickness of the first multi-material conductive pad, and
a thickness of the fourth conductive material of the second multi-material conductive pad is between about 10% and about 40% of a total thickness of the second multi-material conductive pad.

12. The electronic system of claim 8, wherein:
the first microelectronic device structure further comprises first conductive pads and a first dielectric material adjacent to the first conductive pads;
the second microelectronic device structure further comprises second conductive pads and a second dielectric material adjacent to the second conductive pads; and
the first conductive pads are bonded to the second conductive pads, and the first dielectric material is bonded to the second dielectric material.

13. The electronic system of claim 8, wherein the bonded first and second conductive pads comprise an intermetallic compound.

14. A method for fabricating a three-dimensional integrated circuit, the method comprising:
forming first bond pads on a first die, and forming second bond pads on a second die;
forming first conductive pads adjacent to the first bond pads of the first die, and forming second conductive pads adjacent to the second bond pads of the second die;
removing a portion of at least one, but not all, of the first conductive pads to form at least one first recessed conductive pad, and removing a portion of at least one, but not all, of the second conductive pads to form at least one second recessed conductive pad;
forming a first conductive material onto the at least one first recessed conductive pad to form at least one first multi-material conductive pad, and forming a second conductive material onto the at least one second recessed conductive pad to form at least one second multi-material conductive pad; and
bonding the first multi-material conductive pad and the second multi-material conductive pad to join the first die to the second die and to form the three-dimensional integrated circuit.

15. The method of claim 14, wherein bonding the first multi-material conductive pad and the second multi-material conductive pad comprises metal diffusion bonding the first multi-material conductive pad and the second multi-material conductive pad.

16. The method of claim 15, wherein bonding the first multi-material conductive pad and the second multi-material conductive pad comprises applying heat and pressure to the first die and the second die.

17. The method of claim 14, further comprising forming a first dielectric material on the first die between the first conductive pads and forming a second dielectric material on the second die between the second conductive pads and bonding the first dielectric material to the second dielectric material.

18. The method of claim 17, wherein:
forming the first conductive material onto the at least one first recessed conductive pad comprises forming the first conductive material on the first dielectric material, the first conductive pads, and the at least one first recessed conductive pad, the method further comprising removing the first conductive material from the first dielectric material and the first conductive pads to form the at least one first multi-material conductive pad; and
forming the second conductive material onto the at least one second recessed conductive pad comprises forming the second conductive material on the second dielectric material, the second conductive pads, and the at least one second recessed conductive pad, the method further comprising removing the second conductive material from the second dielectric material and the second conductive pads to form the at least one second multi-material conductive pad.

19. The method of claim 14, wherein removing a portion of at least one, but not all, of the first conductive pads comprises etching between about 10% and about 50% of a height of the at least one of the first conductive pads to form the first recessed conductive pad, and wherein removing a portion of at least one, but not all, of the second conductive pads comprises etching between about 10% and about 50% of a height of the at least one of the second conductive pads to form the second recessed conductive pad.

20. The method of claim 14, further comprising planarizing the first conductive material and the second conductive material before bonding the first multi-material conductive pad and the second multi-material conductive pad.
